(19) United States
(12) Patent Application Publication
(10) Pub. No.: US 2004/0238213 A1
(43) Pub. Date: Dec. 2, 2004

(54) Uniform impedance printed circuit board

(76) Inventor: Walter Michael Pitio, Morganville, NJ (US)

Correspondence Address: DEMONT & BREYER, LLC, SUITE 250, 100 COMMONS WAY, HOLMDEL, NJ, 07733, US

(21) Appl. No.: 10/446,361

(22) Filed: May 28, 2003

(51) Int. Cl. H05K 7/06

(52) U.S. Cl. 174/262

(57) ABSTRACT

A technique for ameliorating the reflections on traces on printed circuit boards is taught that seeks to present a uniform—or more uniform—impedance profile to a trace as it traverses the printed circuit board. In the illustrative embodiments, this is accomplished by adding grounded vias to the printed circuit board in places and densities outside the connector footprints so that the linear density and proximity of the added ground vias along each trace is similar or identical to the density and proximity of the ground vias along the trace within a connector footprint.

### FIELD OF THE INVENTION

The present invention relates to electrical engineering in general, and, more particularly, to a technique for improving the layout of printed circuit boards.

### BACKGROUND OF THE INVENTION

FIG. 1 depicts one layer of a printed circuit board, printed circuit board 100, in accordance with the prior art. Printed circuit board 100 comprises: seven groups of vias that are associated with connector footprints 111 through 117. Printed circuit board 100 comprises one or more layers and is manufactured with materials and processes that are well known to those skilled in the art. Furthermore, connectors (e.g., integrated circuit packages, etc.), surface-mount components, and other devices are affixed—both mechanically and electrically—in well-known fashion.

Connector footprints 111, 112, and 113 each comprise a 6 by 6 orthogonal array of vias, and connector footprints 114, 115, 116, and 117 each comprise a 6 by 4 orthogonal array of vias. Some of these vias—depicted as white circles—transport information-bearing signals between a connector (not shown) and printed circuit board 100. In contrast, some of the vias—depicted as black circles—are grounded to one or more ground planes within printed circuit board 100. The purpose of the ground vias is to provide a measure of electromagnetic isolation between the signal vias. In other words, the presence of the grounded vias attenuates the amount of electromagnetic interference that an information-bearing signal on one signal via imparts to another information-bearing signal on another signal via.

FIG. 2 depicts one layer of printed circuit board 100, in accordance with the prior art, in which trace 120 provides an electrical connection between signal via 111-1 within connector footprint 111 and signal via 117-1 within connector footprint 117. An electromagnetic signal on trace 120 experiences a change in impedance when it enters and exits connector footprint 112, and, therefore, reflections will be created on trace 120. These reflections hinder the ability of trace 120 to carry high-frequency signals, and, therefore, the need exists for a technique that ameliorates these reflections.

### SUMMARY OF THE INVENTION

The present invention provides a technique for diminishing or eliminating the reflections on traces on printed circuit boards without some of the costs and disadvantages for doing so in the prior art. In particular, the present invention recognizes that the reflections on traces on printed circuit boards are at least partially caused by the non-uniform impedance profile that is presented to the trace as the trace's proximity to ground vias changes as it traverses the printed circuit board. Typically, the trace's proximity to ground vias is different when the trace passes through connector footprints where there are ground vias in close proximity in contrast to when the trace passes between connector footprints where there are few, if any, ground vias in close proximity.

Therefore, the present invention seeks to present a uniform—or more uniform—impedance profile to a trace as it traverses the printed circuit board.

In the illustrative embodiments, this is accomplished by adding grounded vias to the printed circuit board in places and densities outside the connector footprints so that the linear density and proximity of the added ground vias along each trace is identical—or as close—to the linear density and proximity of the ground vias along the trace within a connector footprint.

When a trace is significantly straight, the pattern of added vias can usually be made to mimic the pattern of vias in the connector footprints that are proximate to the trace. In contrast, when a trace has a significant bend in it, the added ground vias not within the connector footprints are sited on the printed circuit board to provide the trace with a two-dimensional field of grounded vias in which the density and proximity of the ground vias in both the X-dimension and the Y-dimension are as close as possible to the density of ground vias in the dimension of the connector footprints in which the trace exists and enters the connector footprint. In other words, if the connector footprint has a mean density of \overline{X} ground vias per millimeters in the X dimension and a mean density of \overline{Y} grounded vias per millimeters in the Y dimension, then the added ground vias also have a mean density of \overline{X} ground vias per millimeters in the X dimension and a mean density of \overline{Y} grounded vias per millimeters in the Y dimension. This enables the trace to bend and before, during, and after the bend to experience an identical or nearly identical impedance profile. Furthermore, this also enables multiple superimposed traces—each on different layers of the printed circuit board that are separated by ground planes—to follow one another, to cross over each other, and to bend in similar or different directions within the same group of ground vias.

The illustrative embodiment comprises: a first signal via in the printed circuit board, wherein the first signal via transports a first information-bearing signal between the printed circuit board and a first connector; a second signal via in the printed circuit board, wherein the second signal via transports the first information-bearing signal between the printed circuit board and a second connector; a first trace between the first signal via and the second signal via for electrically connecting the first signal via to the second signal via; a first plurality of grounded vias surrounding the first signal via, wherein the first plurality of grounded vias electrically connect the first connector to ground, and wherein the first plurality of grounded vias has a mean density of \overline{X} ground vias per millimeters in a first dimension; a second plurality of grounded vias surrounding the second signal via, wherein the second plurality of grounded vias electrically connect the second connector to ground, and wherein the second plurality of grounded vias has a mean density of \overline{X} ground vias per millimeters in the first dimension; and a third plurality of grounded vias surrounding the first trace, wherein the third plurality of grounded vias has a mean density of \overline{X} ground vias per millimeters in the first dimension; wherein \overline{X} is a positive real number.

### BRIEF DESCRIPTION OF THE DRAWINGS

FIG. 1 depicts a plurality of signal vias and ground vias in a printed circuit board in the prior art.

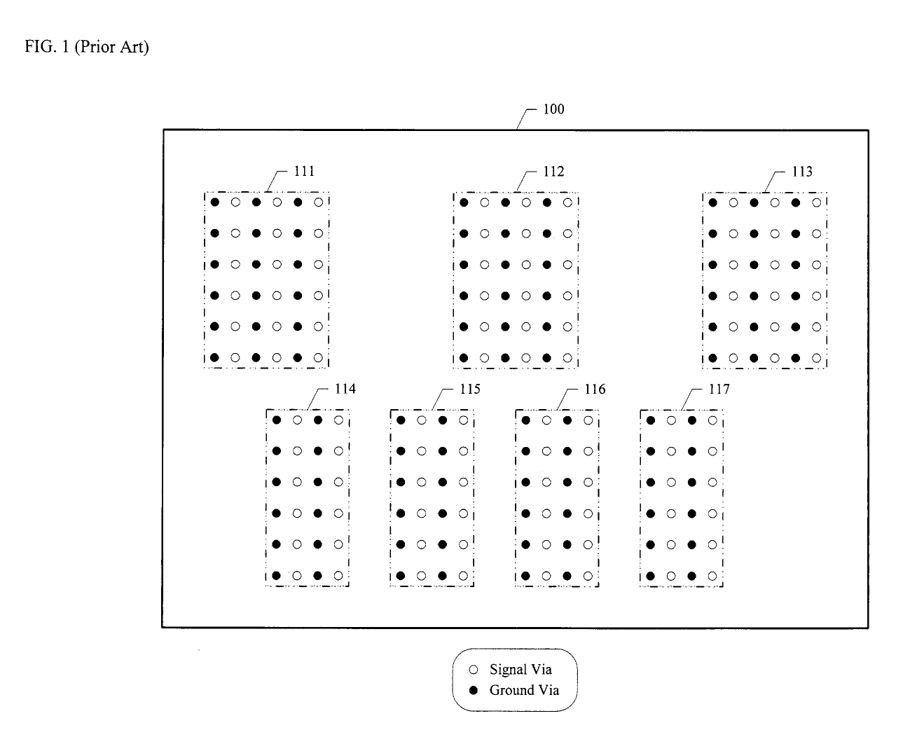

FIG. 2 depicts a trace on the printed circuit board depicted in FIG. 1.

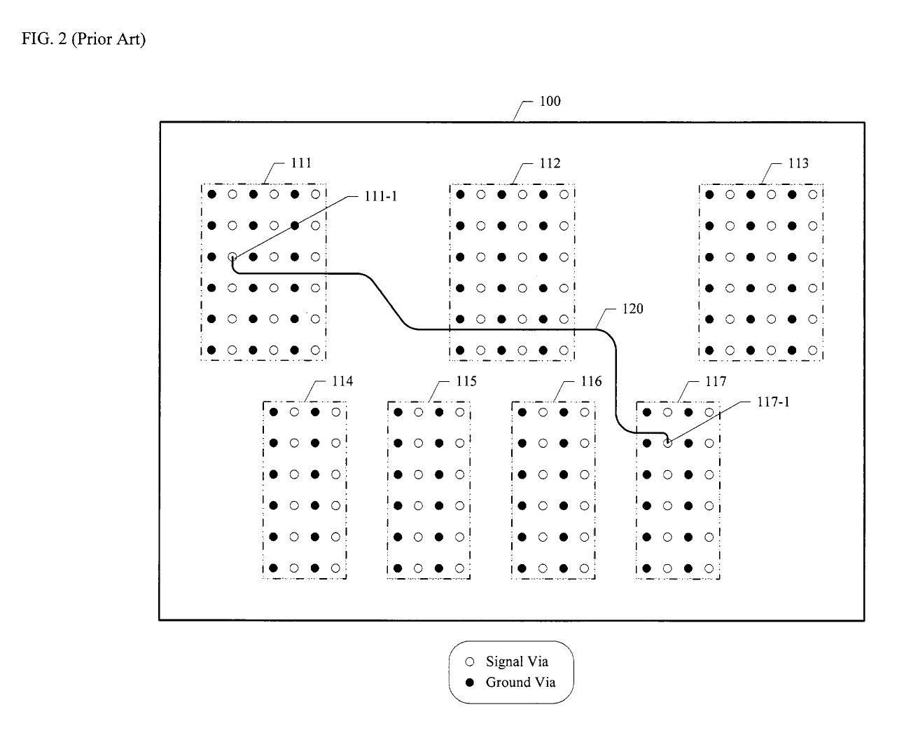

FIG. 3 depicts a printed circuit board in accordance with the first illustrative embodiment of the present invention.

FIG. 4 depicts a printed circuit board in accordance with the second illustrative embodiment of the present invention.

FIG. 5 depicts a printed circuit board in accordance with the third illustrative embodiment of the present invention.

### DETAILED DESCRIPTION

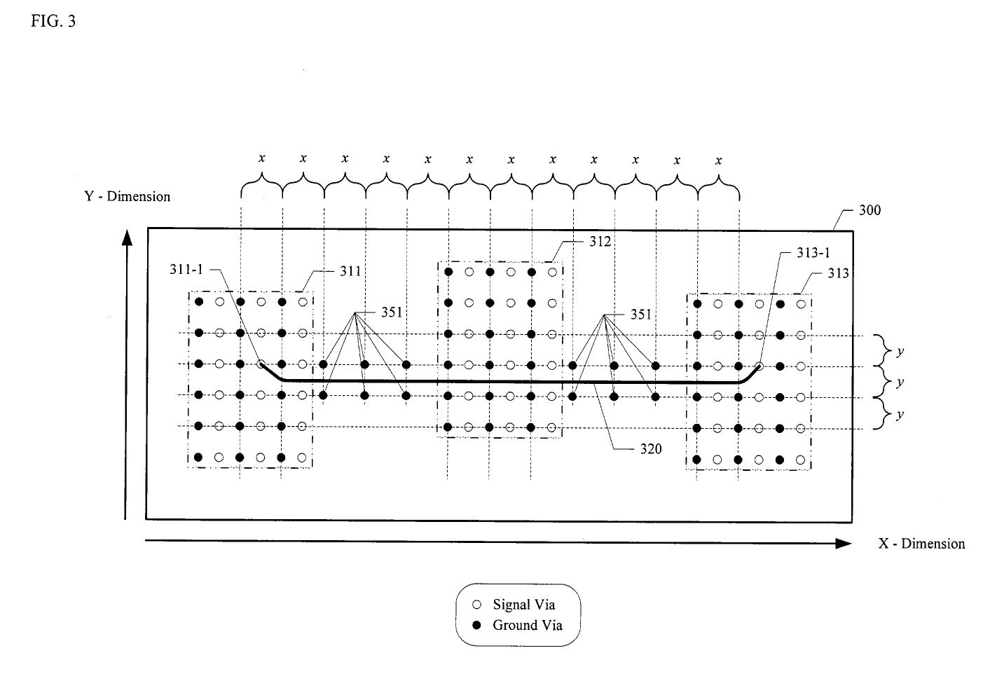

FIG. 3 depicts one layer of a printed circuit board, printed circuit board 300, in accordance with the first illustrative embodiment of the present invention. Printed circuit board 300 comprises: three groups of vias that are associated with connector footprints 311, 312, and 313, vias 351, which are not associated with a connector, and trace 320. Printed circuit board 300 comprises one or more layers and is manufactured with materials and processes that are well known to those skilled in the art. Furthermore, connectors (e.g., integrated circuit packages, etc.), surface-mount components, and other devices are affixed—both mechanically and electrically—in well-known fashion.

Connector footprints 311, 312, and 313 each comprise a 6 by 6 orthogonal array of vias. Some of these vias—depicted as white circles—transport information-bearing signals between a connector (not shown) and printed circuit board 300. In contrast, some of the vias—depicted as black circles are grounded. The purpose of the grounded vias is to provide a measure of electromagnetic isolation between the signal vias. In other words, the presence of the grounded vias attenuates the amount of electromagnetic interference that an information-bearing signal on one signal via imparts to another information-bearing signal on another signal via.

The ground vias within connector footprints 311, 312, and 313 are uniformly spaced at x millimeters apart in the X dimension and y millimeters apart in the Y dimension, wherein x and y are positive real numbers. Furthermore, connector footprints 311, 312, and 313 are sited on printed circuit board 300 so that their respective columns of grounded vias are an integral multiple of x millimeters apart in the X dimension and collinear in the Y dimension, as shown.

Trace 320 provides an electrical connection between signal via 311-1 within connector footprint 311 and signal via 313-1 within connector footprint 313. Trace 320 is substantially straight along its course from signal via 311-1 to signal via 313-1, and its corners are rounded.

To provide a uniform—or more-nearly-uniform—impedance profile to the information-bearing signal on trace 320, trace 320 is surrounded by grounded vias along its entire length. Some of these grounded vias are within connector footprints 311, 312, and 313 and others are not.

Ground vias 351 are sited on printed circuit board 300 to surround trace 320 and to match the pattern of ground vias surrounding trace 320 within connector footprints 311, 312, and 313. Therefore, ground vias 351 are uniformly spaced to be x millimeters apart in the X dimension and y millimeters apart in the Y dimension. To enhance the uniform impedance profile, trace 320 is sited on printed circuit board 300 to be equidistant between the ground vias that surround it.

In accordance with the first illustrative embodiment, trace 320 transports a time-varying information-bearing signal. The information-bearing signal has rising edges and falling edges and these rising and falling edges must be clean so as to retain a clean “eye” for the receiver. The cleanest eye has the shortest rise and fall times, and, therefore, the highest-frequency frequency component. In accordance with the illustrative embodiment, the highest-frequency frequency component for which printed circuit board 300 is designed has a wavelength of λ millimeters.

Although ground vias 351 are uniformly spaced apart in the first illustrative embodiment, it will be clear to those skilled in the art, after reading this specification, that they need not be. For example, the ground vias within the first connector footprint have a mean density of \overline{X} ground vias per millimeters in the X dimension and a mean density of \overline{Y} grounded vias per millimeters in the Y dimension, then a more-nearly uniform impedance profile is presented when ground vias 351 (and all ground vias within any intermediate connector footprints) also have a mean density of \overline{X} ground vias per millimeters in the X dimension and a mean density of \overline{Y} grounded vias per millimeters in the Y dimension. In accordance with the first illustrative embodiment,

$$\overline{X} < \frac{1}{4 λ} and \overline{Y} < \frac{1}{4 λ} , but \overline{X} < \frac{1}{6 λ} and \overline{Y} < \frac{1}{6 λ}$$

is preferable.

Although the first illustrative embodiment depicts a printed circuit board with three connector footprints, it will be clear to those skilled in the art, after reading this specification, how to make and use embodiments of the present invention that comprise other than three connector footprints. Furthermore, although the first illustrative embodiment depicts connector footprints in which the ratio of signal vias to grounded vias is 1:1, it will be clear to those skilled in the art, after reading this specification, how to make and use embodiments of the present invention in which the ratio of signal vias to grounded vias is other than 1:1. And still furthermore, although the first illustrative embodiment comprises only one trace, it will be clear to those skilled in the art, after reading this specification, how to make and use embodiments of the present invention that comprises a plurality of traces.

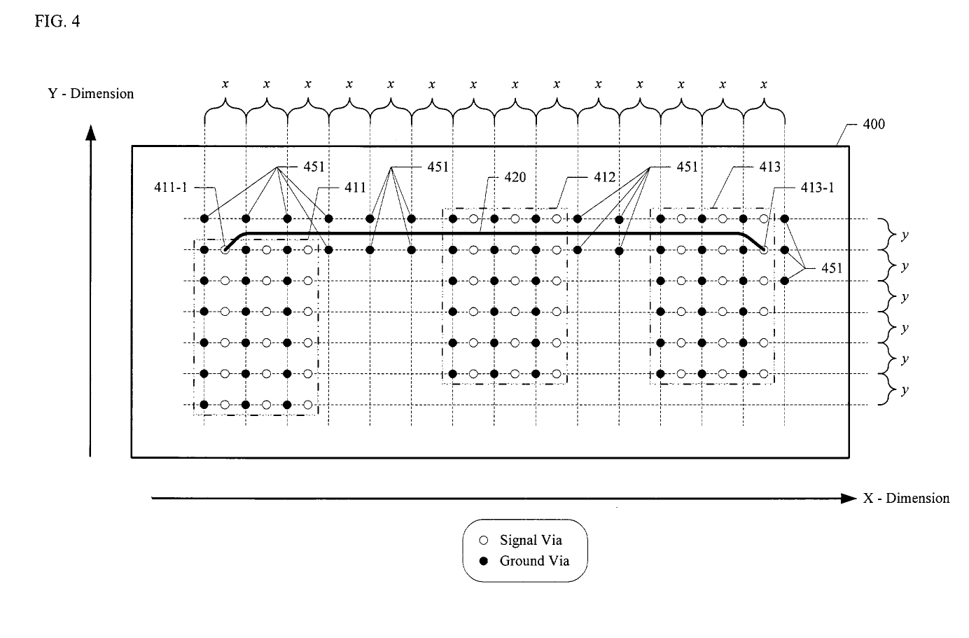

FIG. 4 depicts a printed circuit board, printed circuit board 400, in accordance with the second illustrative embodiment of the present invention. Printed circuit board 400 comprises: three groups of vias that are associated with connector footprints 411, 412, and 413, vias 451, which are not connected with a connector, and trace 420. Printed circuit board 400 comprises one or more layers and it manufactured with materials and processes that are well known to those skilled in the art. Furthermore, connectors (e.g., integrated circuit packages, etc.), surface-mount components, and other devices are affixed—both mechanically and electrically—in well-known fashion.

Connector footprints 411, 412, and 413 each comprise a 6 by 6 orthogonal array of vias. Some of these vias—depicted as white circles—transport information-bearing signals between a connector (not shown) and printed circuit board 400. In contrast, some of the vias—depicted as black circles—are grounded. The purpose of the grounded vias is to provide a measure of electromagnetic isolation between the signal vias. In other words, the presence of the grounded vias attenuates the amount of electromagnetic interference that an information-bearing signal on one signal via imparts to another information-bearing signal on another signal via.

The ground vias within connector footprints 411, 412, and 413 are uniformly spaced to be x millimeters apart in the X dimension and y millimeters apart in the Y dimension, wherein x and y are positive real numbers. Furthermore, connector footprints 411, 412, and 413 are sited on printed circuit board 400 so that their respective columns of grounded vias are a multiple of x millimeters apart in the X dimension and collinear in the Y dimension, as shown.

Trace 420 provides an electrical connection between signal via 411-1 within connector footprint 411 and signal via 413-1 within connector footprint 413. Trace 420 is substantially straight along its course from signal via 411-1 to signal via 413-1, and its corners are rounded.

To provide a uniform—or more-nearly-uniform—impedance profile to the information-bearing signal on trace 420, trace 420 is surrounded by grounded vias along its entire length. Some of these grounded vias are within connector footprints 411, 412, and 413 and others are not.

Ground vias 451 are sited on printed circuit board 400 to surround trace 420 and to match the pattern of ground vias surrounding trace 420 within connector footprints 412 and 413. The second illustrative embodiment is different than the first illustrative embodiment in that second illustrative embodiment ground vias 451 are placed on two adjacent sides of a connector footprint, connector footprint 411. Therefore, ground vias 451 are uniformly spaced to be x millimeters apart in the X dimension and y millimeters apart in the Y dimension. To enhance the uniform impedance profile, trace 420 is sited on printed circuit board 400 to be equidistant between the ground vias that surround it.

In accordance with the second illustrative embodiment, trace 420 transports a time-varying information-bearing signal. The information-bearing signal has rising edges and falling edges and these rising and falling edges must be clean so as to retain a clean “eye” for the receiver. The cleanest eye has the shortest rise and fall times, and, therefore, the highest-frequency frequency component. In accordance with the illustrative embodiment, the highest-frequency frequency component for which printed circuit board 400 is designed has a wavelength of λ millimeters.

Although ground vias 451 are uniformly spaced apart in the second illustrative embodiment, it will be clear to those skilled in the art, after reading this specification, that they need not be. For example, the ground vias within the second connector footprint have a mean density of \overline{X} ground vias per millimeters in the X dimension and a mean density of \overline{Y} grounded vias per millimeters in the Y dimension, then a more-nearly uniform impedance profile is presented when ground vias 451 (and all ground vias within any intermediate connector footprints) also have a mean density of \overline{X} ground vias per millimeters in the X dimension and a mean density of \overline{Y} grounded vias per millimeters in the Y dimension. In accordance with the second illustrative embodiment,

$$\overline{X} < \frac{1}{4 λ} and \overline{Y} < \frac{1}{4 λ} , but \overline{X} < \frac{1}{6 λ} and \overline{Y} < \frac{1}{6 λ}$$

is preferable.

Although the second illustrative embodiment depicts a printed circuit board with three connector footprints, it will be clear to those skilled in the art, after reading this specification, how to make and use embodiments of the present invention that comprise other than three connector footprints. Furthermore, although the second illustrative embodiment depicts connector footprints in which the ratio of signal vias to grounded vias is 1:1, it will be clear to those skilled in the art, after reading this specification, how to make and use embodiments of the present invention in which the ratio of signal vias to grounded vias is other than 1:1. And still furthermore, although the second illustrative embodiment comprises only one trace, it will be clear to those skilled in the art, after reading this specification, how to make and use embodiments of the present invention that comprises a plurality of traces.

In both the first and the second illustrative embodiments, the depicted trace was nearly straight along its path. In contrast, in the third illustrative embodiment, the traces have substantial bends in them. Furthermore, in the first and second illustrative embodiments, the trace represented a single unpaired signal. In contrast, in the third illustrative embodiment, each trace is one-half of a high-speed differential pair. And still furthermore, in the third illustrative embodiment, the depicted traces are part of a parallel bus.

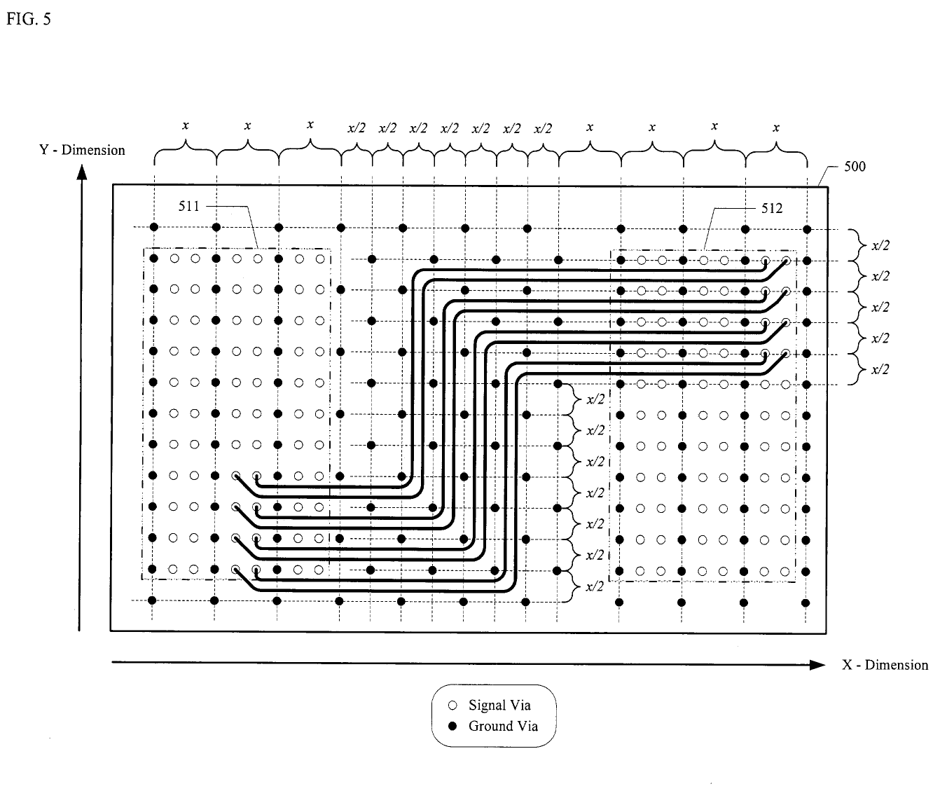

FIG. 5 depicts a printed circuit board, printed circuit board 500, in accordance with the third illustrative embodiment of the present invention. Printed circuit board 500 comprises: two groups of vias that are associated with connector footprints 511 and 512, a plurality of vias that are not connected with a connector, and eight traces. Printed circuit board 500 comprises one or more layers and it manufactured with materials and processes that are well known to those skilled in the art. Furthermore, connectors (e.g., integrated circuit packages, etc.), surface-mount components, and other devices are affixed—both mechanically and electrically—in well-known fashion.

Connector footprints 511 and 512 each comprise an 11 by 9 orthogonal array of vias. Some of these vias—depicted as white circles—transport information-bearing signals between a connector (not shown) and printed circuit board 500. In contrast, some of the vias—depicted as black circles—are grounded. The purpose of the grounded vias is to provide a measure of electromagnetic isolation between the signal vias. In other words, the presence of the grounded vias attenuates the amount of electromagnetic interference that an information-bearing signal on one signal via imparts to another information-bearing signal on another signal via.

The ground vias within connector footprints 511 and 512 are uniformly spaced to be x millimeters apart in the X dimension and y millimeters apart in the Y dimension, wherein x and y are positive real numbers. Furthermore, connector footprints 511 and 512 are sited on printed circuit board 500 so that their respective columns of grounded vias are an integral multiple of x/2 millimeters apart in the X dimension and collinear in the Y dimension, as shown.

Each of the eight depicted traces provides an electrical connection between a signal via within connector footprint 511 and a signal via within connector footprint 512. Each of the eight depicted traces has two right-angle bends along its course from the signal via within connector footprint 511 to the signal via within connector footprint 512.

To provide a uniform—or more-nearly-uniform—impedance profile to the information-bearing signal on each of the eight depicted traces, the traces are surrounded by grounded vias along their entire length. Some of these grounded vias are within connector footprints 511 and 512 and others are not.

The ground vias not within a connector footprint are sited on printed circuit board 500 to surround the traces and to create a two-dimensional field of grounded footprints in which the density of ground vias in both the X-dimension and the Y-dimension is substantially close to the density of ground vias in the X-dimension within connector footprints 511 and 512. In other words, the linear density of ground vias along each trace, whether the trace is traveling in the X-dimension or the Y-dimension, should be identical—or as close as possible to—the linear density of ground vias along each trace within a connector footprint. Therefore, ground vias are sited on alternate intersections of a lattice in which the rows and columns are each x/2 millimeters apart, as shown in FIG. 5.

In accordance with the third illustrative embodiment, each trace transports a time-varying information-bearing signal. The information-bearing signal has rising edges and falling edges and these rising and falling edges must be clean so as to retain a clean “eye” for the receiver. The cleanest eye has the shortest rise and fall times, and, therefore, the highest-frequency frequency component. In accordance with the illustrative embodiment, the highest-frequency frequency component for which printed circuit board 500 is designed has a wavelength of λ millimeters. Although the ground vias not within connector footprint 511 or 512 are uniformly spaced apart in the third illustrative embodiment, it will be clear to those skilled in the art, after reading this specification, that they need not be. For example, the ground vias within the connector footprint 511 and 512 have a mean density of \overline{X} ground vias per millimeters in the X dimension, then a more-nearly uniform impedance profile is presented when the ground vias not within a connector footprint also have a mean density of \overline{X} ground vias per millimeters in the X dimension. In accordance with the third illustrative embodiment,

$$\overline{X} < \frac{1}{4 λ} and \overline{Y} < \frac{1}{4 λ} , but \overline{X} < \frac{1}{6 λ} and \overline{Y} < \frac{1}{6 λ}$$

is preferable.

Although the third illustrative embodiment depicts a printed circuit board with two connector footprints, it will be clear to those skilled in the art, after reading this specification, how to make and use embodiments of the present invention that comprise other than two connector footprints. Furthermore, although the second illustrative embodiment depicts connector footprints in which the ratio of signal vias to grounded vias is 2:1, it will be clear to those skilled in the art, after reading this specification, how to make and use embodiments of the present invention in which the ratio of signal vias to grounded vias is other than 2:1. And still furthermore, although the second illustrative embodiment comprises only eight traces, it will be clear to those skilled in the art, after reading this specification, how to make and use embodiments of the present invention that comprises other than eight traces.

It is to be understood that the above-described embodiments are merely illustrative of the present invention and that many variations of the above-described embodiments can be devised by those skilled in the art without departing from the scope of the invention. It is therefore intended that such variations be included within the scope of the following claims and their equivalents.

What is claimed is:

1. A printed circuit board comprising:
a first signal via in said printed circuit board, wherein said first signal via transports a first information-bearing signal between said printed circuit board and a first connector;
a second signal via in said printed circuit board, wherein said second signal via transports said first information-bearing signal between said printed circuit board and a second connector;
a first trace between said first signal via and said second signal via for electrically connecting said first signal via to said second signal via;
a first plurality of grounded vias surrounding said first signal via, wherein said first plurality of grounded vias electrically connect said first connector to ground, and wherein said first plurality of grounded vias has a mean density of \overline{X} ground vias per millimeters in a first dimension;
a second plurality of grounded vias surrounding said second signal via, wherein said second plurality of grounded vias electrically connect said second connector to ground, and wherein said second plurality of grounded vias has a mean density of \overline{X} ground vias per millimeters in said first dimension; and
a third plurality of grounded vias surrounding said first trace, wherein said third plurality of grounded vias has a mean density of \overline{X} ground vias per millimeters in said first dimension;
wherein \overline{X} is a positive real number.

2. The printed circuit board of claim 1 wherein said first plurality of grounded vias have a mean density of \overline{Y} grounded vias per millimeters in a second dimension;
wherein said second plurality of grounded vias have a mean density of \overline{Y} grounded vias per millimeters in said second dimension;
wherein said third plurality of grounded vias have a mean density of \overline{Y} grounded vias per millimeters in said third dimension; and
wherein said second dimension is perpendicular to said first dimension.

3. The printed circuit board of claim 1 wherein said third plurality of grounded vias has a mean density of 3\overline{X} ground vias per square millimeters.

4. The printed circuit board of claim 1 wherein said first information-bearing signal has a frequency component with a wavelength of λ millimeters, and wherein
$$\overline{X} < \frac{1}{4 λ} .$$

5. The printed circuit board of claim 1 further comprising:
a third signal via in said printed circuit board, wherein said third signal via transports a second information-bearing signal between said printed circuit board and said first connector;
a fourth signal via in said printed circuit board, wherein said fourth signal via transports said second information-bearing signal between said printed circuit board and said second connector; and
a second trace between said third signal via and said fourth signal via for electrically connecting said third signal via to said fourth signal via;
wherein said first information-bearing signal and said second information-bearing signal together comprise a differential pair.

6. The printed circuit board of claim 5 wherein said first trace and said second trace are surrounded by the same grounded vias.

7. The printed circuit board of claim 1 wherein said first information-bearing signal has a wavelength of λ millimeters, and wherein said first trace has a substantially-uniform impedance for signals with a wavelength of λ millimeters and longer.

8. A printed circuit board comprising:
a first signal via in said printed circuit board, wherein said first signal via transports a first information-bearing signal between said printed circuit board and a first connector;
a second signal via in said printed circuit board, wherein said second signal via transports said first information-bearing signal between said printed circuit board and a second connector;
a first trace between said first signal via and said second signal via for electrically connecting said first signal via to said second signal via; and
a plurality of grounded vias surrounding said first trace;
wherein said first information-bearing signal has a frequency component with a wavelength of λ millimeters; and
wherein said first trace has a substantially-uniform impedance for signals with a wavelength of λ millimeters and longer.

9. The printed circuit board of claim 8 wherein said plurality of grounded vias has a mean density of at least 3 grounded vias per λ² square millimeters within a region bounded by one λ of said trace.

10. An article comprising:
a first connector footprint in said article that comprises a first orthogonal array of grounded vias whose columns are x millimeters apart and whose rows are y millimeters apart;
a second connector footprint in said article that comprises a second orthogonal array of grounded vias whose columns are x millimeters apart and whose rows are y millimeters apart;
wherein said columns of said first connector footprint are an integral multiple of x/2 millimeters apart from said column of said second connector footprint.

13. The article of claim 10 wherein said rows of said first connector footprint are collinear with said rows of said second connector footprint.

14. The article of claim 10 further comprising a plurality of grounded vias between said first connector footprint and said second connector footprint that have a linear mean density in a first dimension equal to the linear mean density of said grounded vias in said first dimension in said first orthogonal array.

15. The article of claim 10 wherein said plurality of grounded vias between said first connector footprint and said second connector footprint have a linear mean density in a second dimension equal to the linear mean density of said grounded vias in said first dimension in said first orthogonal array;
wherein said first dimension is perpendicular to said second dimension.

16. The article of claim 10 wherein said plurality of grounded vias between said first connector footprint and said second connector footprint have a linear mean density in a second dimension equal to the linear mean density of said grounded vias in said second dimension in said first orthogonal array;
wherein said first dimension is perpendicular to said second dimension.
